(19) United States
(12) Patent Application Publication
(10) Pub. No.: US 2016/0291478 A1
(43) Pub. Date: Oct. 6, 2016

(54) CATALYTIC PHOTORESIST FOR PHOTOLITHOGRAPHIC METAL MESH TOUCH SENSOR FABRICATION

(71) Applicant: Uni-Pixel Displays, Inc., The Woodlands, TX (US)

(72) Inventor: Robert J. Petcavich, The Woodlands, TX (US)

(21) Appl. No.: 14/674,372

(22) Filed: Mar. 31, 2015

(51) Int. Cl. G03F 7/42; G03F 7/16; G03F 7/32; G03F 7/40; G03F 7/038; G03F 7/20

(52) U.S. Cl. CPC G03F 7/42; G03F 7/038; G03F 7/2022; G03F 7/32; G03F 7/40; G03F 7/16

(57) ABSTRACT

A catalytic photoresist composition includes a negative photoresist component and a catalyst component that includes catalytic nanoparticles. The negative photoresist component content is in a range between 30 percent and 95 percent of the composition by weight. The catalyst component content is in a range between 5 percent and 70 percent of the composition by weight.

### BACKGROUND OF THE INVENTION

A touch screen enabled system allows a user to control various aspects of the system by touch or gestures on the screen. A user may interact directly with one or more objects depicted on a display device by touch or gestures that are sensed by a touch sensor. The touch sensor typically includes a conductive pattern disposed on a substrate configured to sense touch. Touch screens are commonly used in consumer, commercial, and industrial systems.

### BRIEF SUMMARY OF THE INVENTION

According to one aspect of one or more embodiments of the present invention, a catalytic photoresist composition includes a negative photoresist component and a catalyst component that includes catalytic nanoparticles. The negative photoresist component content is in a range between 30 percent and 95 percent of the composition by weight. The catalyst component content is in a range between 5 percent and 70 percent of the composition by weight.

According to one aspect of one or more embodiments of the present invention, a method of fabricating a metal mesh touch sensor includes disposing catalytic photoresist on at least a portion of a first side of a transparent substrate and disposing catalytic photoresist on at least a portion of a second side of the substrate. At least a portion of the catalytic photoresist disposed on the first side of the substrate is exposed to ultraviolet radiation through a first photomask. The first photomask includes a negative image of a first conductive pattern. At least a portion of the catalytic photoresist disposed on the second side of the substrate is exposed to ultraviolet radiation through a second photomask. The second photomask includes a negative image of a second conductive pattern. A developer is applied to the catalytic photoresist disposed on the substrate. The catalytic photoresist not exposed to ultraviolet radiation is stripped. The at least portions of the catalytic photoresist exposed to ultraviolet radiation are plated.

Other aspects of the present invention will be apparent from the following description and claims.

### BRIEF DESCRIPTION OF THE DRAWINGS

FIG. 1 shows a cross section of a touch screen in accordance with one or more embodiments of the present invention.

FIG. 2 shows a schematic view of a touch screen enabled system in accordance with one or more embodiments of the present invention.

FIG. 3 shows a functional representation of a touch sensor as part of a touch screen in accordance with one or more embodiments of the present invention.

FIG. 4 shows a cross-section of a touch sensor with conductive patterns disposed on opposing sides of a transparent substrate in accordance with one or more embodiments of the present invention.

FIG. 5A shows a first conductive pattern disposed on a transparent substrate in accordance with one or more embodiments of the present invention.

FIG. 5B shows a second conductive pattern disposed on a transparent substrate in accordance with one or more embodiments of the present invention.

FIG. 5C shows a mesh area of a metal mesh touch sensor in accordance with one or more embodiments of the present invention.

FIG. 6A shows standoff layers disposed on opposing sides of a transparent substrate as part of a conventional method of fabricating a metal mesh touch sensor.

FIG. 6B shows catalyst layers disposed on the opposing standoff layers.

FIG. 6C shows photoresist layers disposed on the opposing catalyst layers.

FIG. 6D shows oxygen protection layers disposed on the opposing photoresist layers.

FIG. 6E shows photomasks disposed on, or placed very near, the opposing oxygen protection layers.

FIG. 6F shows portions of the photoresist layers exposed to UV radiation through the photomasks.

FIG. 6G shows a developer applied to the opposing photoresist layers where the remaining photoresist is stripped.

FIG. 6H shows metal plated on the remaining catalyst.

FIG. 7A shows catalytic photoresist disposed on opposing sides of a transparent substrate in accordance with one or more embodiments of the present invention.

FIG. 7B shows photomasks disposed on, or placed very near, the opposing catalytic photoresist in accordance with one or more embodiments of the present invention.

FIG. 7C shows portions of the catalytic photoresist exposed to UV radiation through the photomasks in accordance with one or more embodiments of the present invention.

FIG. 7D shows a developer applied to the opposing catalytic photoresist in accordance with one or more embodiments of the present invention.

FIG. 7E shows metal plated on remaining catalytic photoresist in accordance with one or more embodiments of the present invention.

### DETAILED DESCRIPTION OF THE INVENTION

One or more embodiments of the present invention are described in detail with reference to the accompanying figures. For consistency, like elements in the various figures are denoted by like reference numerals. In the following detailed description of the present invention, specific details are set forth in order to provide a thorough understanding of the present invention. In other instances, well-known features to one of ordinary skill in the art are not described to avoid obscuring the description of the present invention.

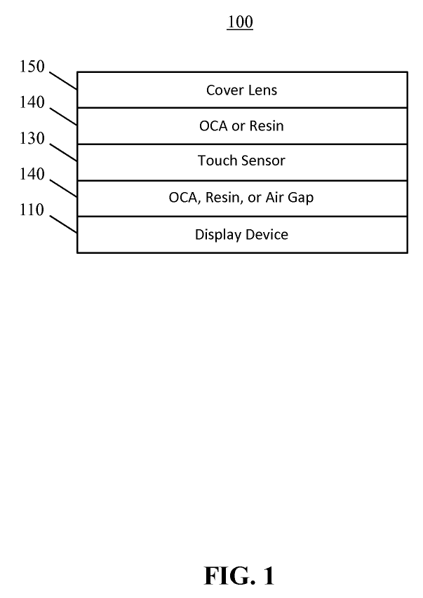

FIG. 1 shows a cross-section of a touch screen 100 in accordance with one or more embodiments of the present invention. Touch screen 100 includes a display device 110 and a touch sensor 130 that overlays at least a portion of a viewable area of display device 110. In certain embodiments, an optically clear adhesive (“OCA”) or resin 140 may bond a bottom side of touch sensor 130 to a top, or user-facing, side of display device 110. In other embodiments, an isolation layer or air gap 140 may separate the bottom side of touch sensor 130 from the top, or user-facing, side of display device 110. A transparent cover lens 150 may overlay a top, or user-facing, side of touch sensor 130. The transparent cover lens 150 may be composed of polyester, glass, or any other material suitable for use as a cover lens 150. In certain embodiments, an OCA or resin 140 may bond a bottom side of the transparent cover lens 150 to the top, or user-facing, side of touch sensor 130. A top side of transparent cover lens 150 faces the user and protects the underlying components of touch screen 100. One of ordinary skill in the art will recognize that the components and/or the stack up of touch screen 100 may vary based on an application or design in accordance with one or more embodiments of the present invention. One of ordinary skill in the art will recognize that touch sensor 130, or the function that it implements, may be integrated into the display device 110 stack up (not independently illustrated) in accordance with one or more embodiments of the present invention.

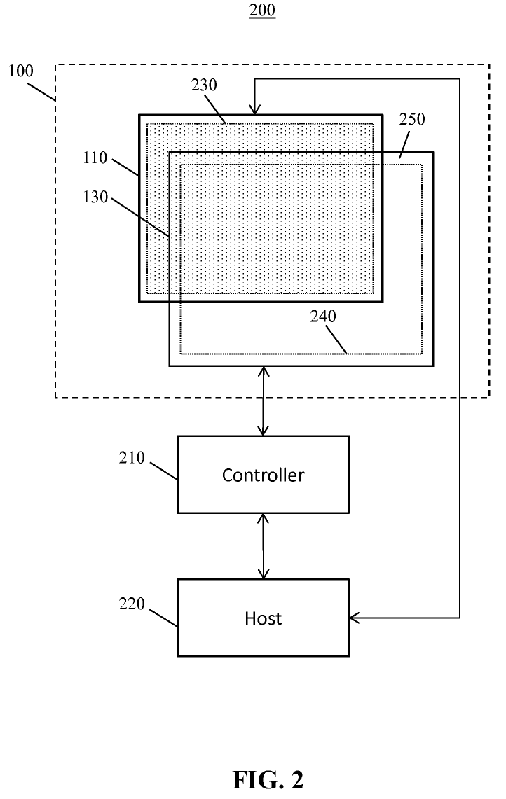

FIG. 2 shows a schematic view of a touch screen enabled system 200 in accordance with one or more embodiments of the present invention. Touch screen enabled system 200 may be a consumer, commercial, or industrial system including, but not limited to, a smartphone, tablet computer, laptop computer, desktop computer, server computer, printer, monitor, television, appliance, application specific device, kiosk, automatic teller machine, copier, desktop phone, automotive display system, portable gaming device, gaming console, or other application or design suitable for use with touch screen 100.

Touch screen enabled system 200 may include one or more printed circuit boards (not shown) or flexible circuits (not shown) on which one or more processors (not shown), system memory (not shown), and other system components (not shown) may be disposed. Each of the one or more processors may be a single-core processor (not shown) or a multi-core processor (not shown) capable of executing software instructions. Multi-core processors typically include a plurality of processor cores disposed on the same physical die (not shown) or a plurality of processor cores disposed on multiple die (not shown) disposed within the same mechanical package (not shown). System 200 may include one or more input/output devices (not shown), one or more local storage devices (not shown) including a solid-state drive, a solid-state drive array, a fixed disk drive, a fixed disk drive array, or any other non-transitory computer readable medium, a network interface device (not shown), and/or one or more network storage devices (not shown) including a network-attached storage device or a cloud-based storage device.

In certain embodiments, touch screen 100 may include touch sensor 130 that overlays at least a portion of a viewable area 230 of display device 110. Touch sensor 130 may include a viewable area 240 that corresponds to that portion of the touch sensor 130 that overlays the light emitting pixels (not shown) of display device 110 (e.g., viewable area 230 of display device 110). Touch sensor 130 may include a bezel circuit area 250 outside at least one side of the viewable area 240 of touch sensor 130 that provides connectivity (not independently illustrated) between touch sensor 130 and a controller 210. In other embodiments, touch sensor 130, or the function that it implements, may be integrated into display device 110 (not independently illustrated). Controller 210 electrically drives at least a portion of touch sensor 130. Touch sensor 130 senses touch (capacitance, resistance, optical, acoustic, or other technology) and conveys information corresponding to the sensed touch to controller 210.

The manner in which the sensing of touch is measured, tuned, and/or filtered may be configured by controller 210. In addition, controller 210 may recognize one or more gestures based on the sensed touch or touches. Controller 210 provides host 220 with touch or gesture information corresponding to the sensed touch or touches. Host 220 may use this touch or gesture information as user input and the system 200 may respond in an appropriate manner. In this way, the user may interact with touch screen enabled system 200 by touch or gestures on touch screen 100. In certain embodiments, host 220 may be the one or more printed circuit boards (not shown) or flexible circuits (not shown) on which the one or more processors (not shown) are disposed. In other embodiments, host 220 may be a subsystem (not shown) or any other part of system 200 (not shown) that is configured to interface with display device 110 and controller 210. One of ordinary skill in the art will recognize that the components and the configuration of the components of touch screen enabled system 200 may vary based on an application or design in accordance with one or more embodiments of the present invention.

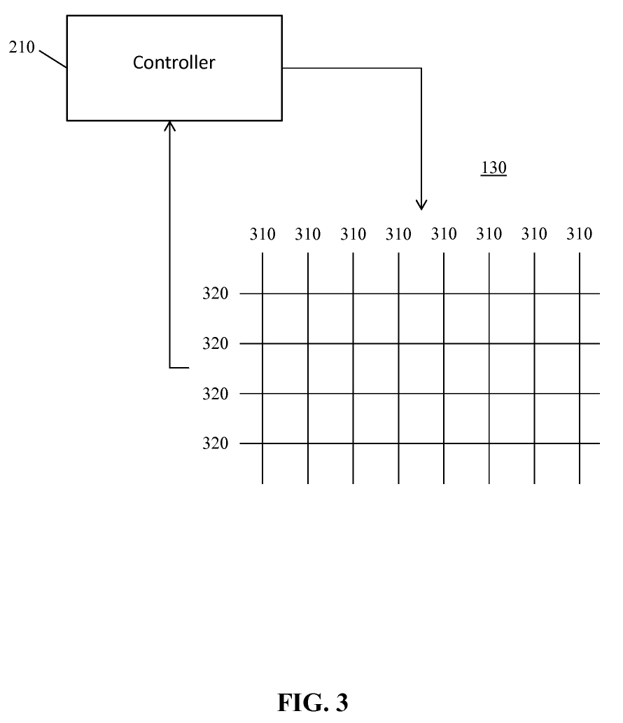

FIG. 3 shows a functional representation of a touch sensor 130 as part of a touch screen 100 in accordance with one or more embodiments of the present invention. In certain embodiments, touch sensor 130 may be viewed as a plurality of column channels 310 and a plurality of row channels 320. The plurality of column channels 310 and the plurality of row channels 320 may be separated from one another by, for example, a dielectric or substrate (not shown) on which they may be disposed. The number of column channels 310 and the number of row channels 320 may or may not be the same and may vary based on an application or a design. The apparent intersections of column channels 310 and row channels 320 may be viewed as uniquely addressable locations of touch sensor 130. In operation, controller 210 may electrically drive one or more row channels 320 and touch sensor 130 may sense touch on one or more column channels 310 that are sampled by controller 210. One of ordinary skill in the art will recognize that the role of row channels 320 and column channels 310 may be reversed such that controller 210 electrically drives one or more column channels 310 and touch sensor 130 senses touch on one or more row channels 320 that are sampled by controller 210.

In certain embodiments, controller 210 may interface with touch sensor 130 by a scanning process. In such an embodiment, controller 210 may electrically drive a selected row channel 320 (or column channel 310) and sample all column channels 310 (or row channels 320) that intersect the selected row channel 320 (or the selected column channel 310) by sensing, for example, changes in capacitance. The change in capacitance may be used to determine the location of the touch or touches. This process may be continued through all row channels 320 (or all column channels 310) such that changes in capacitance are measured at each uniquely addressable location of touch sensor 130 at predetermined intervals. Controller 210 may allow for the adjustment of the scan rate depending on the needs of a particular application or design. In other embodiments, controller 210 may interface with touch sensor 130 by an interrupt driven process. In such an embodiment, a touch or a gesture generates an interrupt to controller 210 that triggers controller 210 to read one or more of its own registers that store sensed touch information sampled from touch sensor 130 at predetermined intervals. One of ordinary skill in the art will recognize that the mechanism by which touch or gestures are sensed by touch sensor 130 and sampled by controller 210 may vary based on an application or a design in accordance with one or more embodiments of the present invention.

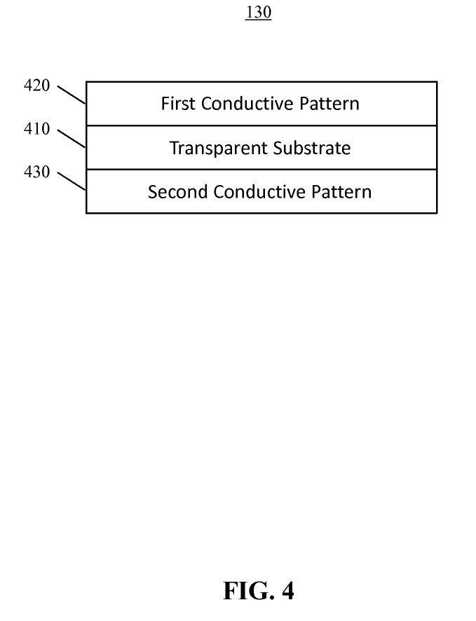

FIG. 4 shows a cross-section of a touch sensor 130 with conductive patterns 420 and 430 disposed on opposing sides of a transparent substrate 410 in accordance with one or more embodiments of the present invention. In certain embodiments, touch sensor 130 may include a first conductive pattern 420 disposed on a top, or user-facing, side of a transparent substrate 410 and a second conductive pattern 430 disposed on a bottom side of the transparent substrate 410. The first conductive pattern 420 and the second conductive pattern 430 may include different, substantially similar, or identical patterns of conductors depending on the application or design. The first conductive pattern 420 may overlay the second conductive pattern 430 at a predetermined alignment that may include an offset. One of ordinary skill in the art will recognize that a conductive pattern may be any shape or pattern of one or more conductors (not shown) in accordance with one or more embodiments of the present invention. One of ordinary skill in the art will also recognize that any type of touch sensor 130 conductor, including, for example, metal conductors, metal mesh conductors, indium tin oxide (“ITO”) conductors, poly(3,4-ethylenedioxythiophene (“PEDOT”) conductors, carbon nanotube conductors, silver nanowire conductors, or any other conductors may be used in accordance with one or more embodiments of the present invention. However, one of ordinary skill in the art will recognize that non-transparent conductors, such as those used in metal mesh touch sensors, are prone to problematic Moire interference.

One of ordinary skill in the art will recognize that other touch sensor 130 stack ups (not shown) may be used in accordance with one or more embodiments of the present invention. For example, single-sided touch sensor 130 stack ups may include conductors disposed on a single side of a substrate 410 where conductors that cross are isolated from one another by a dielectric material (not shown), such as, for example, as used in On Glass Solution (“OGS”) touch sensor 130 embodiments. Double-sided touch sensor 130 stack ups may include conductors disposed on opposing sides of the same substrate 140 (as shown in FIG. 4) or bonded touch sensor 130 embodiments (not shown) where conductors are disposed on at least two different sides of at least two different substrates 410. Bonded touch sensor 130 stack ups may include, for example, two single-sided substrates 410 bonded together (not shown), one double-sided substrate 410 bonded to a single-sided substrate 410 (not shown), or a double-sided substrate 410 bonded to another double-sided substrate 410 (not shown). One of ordinary skill in the art will recognize that other touch sensor 130 stack ups, including those that vary in the number, type, organization, and/or configuration of substrate(s) and/or conductive pattern(s) are within the scope of one or more embodiments of the present invention. One of ordinary skill in the art will also recognize that one or more of the above-noted touch sensor 130 stack ups may be used in applications where touch sensor 130 is integrated into display device 110 in accordance with one or more embodiments of the present invention.

With respect to transparent substrate 410, transparent means capable of transmitting a substantial portion of visible light through the substrate suitable for a given touch sensor application or design. In typical touch sensor applications, transparent means transmittance of at least 85% of incident visible light through the substrate. However, one of ordinary skill in the art will recognize that other transmittance values may be desirable for other touch sensor applications or designs. In certain embodiments, transparent substrate 410 may be polyethylene terephthalate (“PET”), polyethylene naphthalate (“PEN”), cellulose acetate (“TAC”), cycloaliphatic hydrocarbons (“COP”), polymethylmethacrylates (“PMMA”), polyimide (“PI”), bi-axially-oriented polypropylene (“BOPP”), polyester, polycarbonate, glass, copolymers, blends, or combinations thereof. In other embodiments, transparent substrate 410 may be any other transparent material suitable for use as a touch sensor substrate. One of ordinary skill in the art will recognize that the composition of transparent substrate 410 may vary based on an application or design in accordance with one or more embodiments of the present invention.

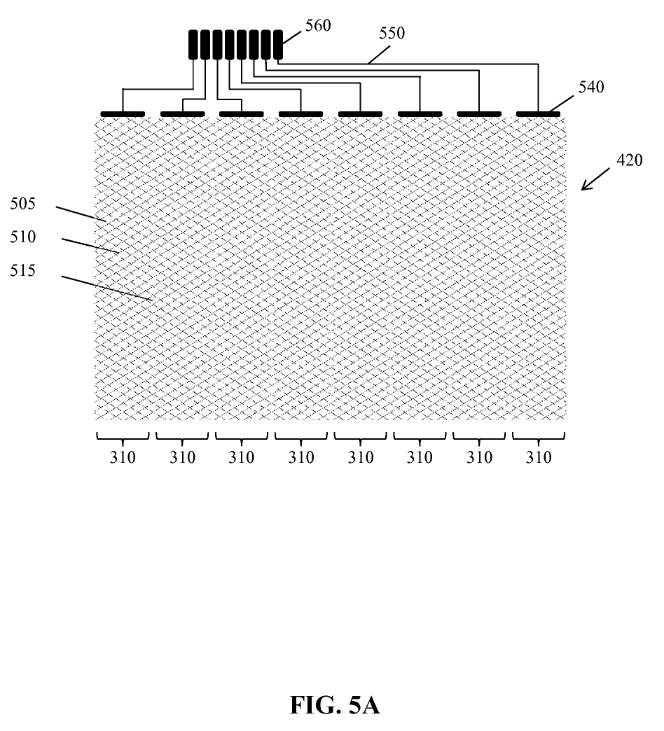

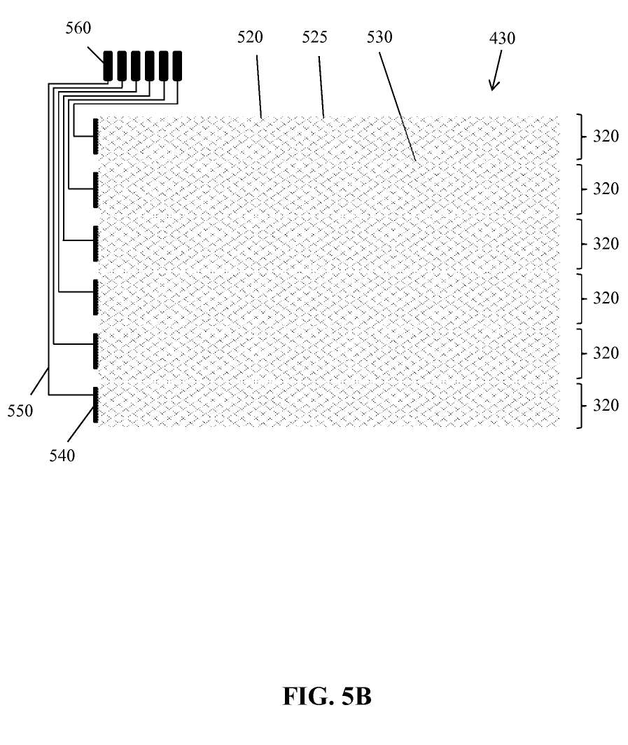

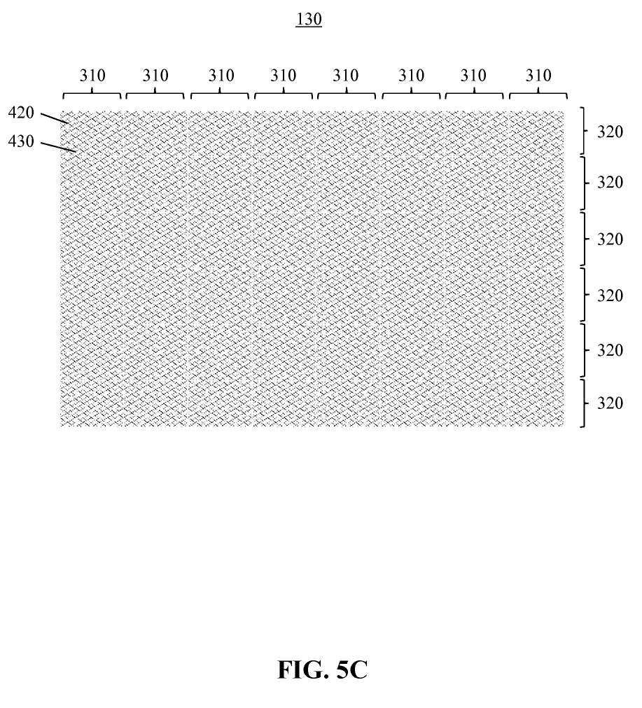

FIG. 5A shows a first conductive pattern 420 disposed on a transparent substrate (e.g., transparent substrate 410) in accordance with one or more embodiments of the present invention. In certain embodiments, first conductive pattern 420 may include a mesh formed by a first plurality of parallel conductive lines oriented in a first direction 505 and a first plurality of parallel conductive lines oriented in a second direction 510 that are disposed on a side of a transparent substrate (e.g., transparent substrate 410). One of ordinary skill in the art will recognize that the number of parallel conductive lines oriented in the first direction 505 and/or the number of parallel conductive lines oriented in the second direction 510 may or may not be the same and may vary based on an application or design. One of ordinary skill in the art will also recognize that a size of first conductive pattern 420 may vary based on an application or a design. In other embodiments, first conductive pattern 420 may include any other shape or pattern formed by one or more conductive lines or features (not independently illustrated). One of ordinary skill in the art will recognize that first conductive pattern 420 is not limited to parallel conductive lines and may comprise any one or more of a predetermined orientation of line segments, a random orientation of line segments, curved line segments, conductive particles, polygons, or any other shape(s) or pattern(s) comprised of electrically conductive material (not independently illustrated) in accordance with one or more embodiments of the present invention.

In certain embodiments, the first plurality of parallel conductive lines oriented in the first direction 505 may be perpendicular (not shown) to the first plurality of parallel conductive lines oriented in the second direction 510, thereby forming a rectangle-type mesh. In other embodiments, the first plurality of parallel conductive lines oriented in the first direction 505 may be angled relative to the first plurality of parallel conductive lines oriented in the second direction 510, thereby forming a parallelogram-type mesh. One of ordinary skill in the art will recognize that the relative angle between the first plurality of parallel conductive lines oriented in the first direction 505 and the first plurality of parallel conductive lines oriented in the second direction 510 may vary based on an application or a design in accordance with one or more embodiments of the present invention.

In certain embodiments, a first plurality of channel breaks 515 may partition first conductive pattern 420 into a plurality of column channels 310, each electrically isolated from the others (no electrical continuity). One of ordinary skill in the art will recognize that the number of channel breaks 515, the number of column channels 310, and/or the width of the column channels 310 may vary based on an application or design in accordance with one or more embodiments of the present invention. Each column channel 310 may route to a channel pad 540. Each channel pad 540 may route via one or more interconnect conductive lines 550 to an interface connector 560. Interface connectors 560 may provide a connection interface between a touch sensor (e.g., 130 of FIG. 2) and a controller (e.g., 210 of FIG. 2).

FIG. 5B shows a second conductive pattern 430 disposed on a transparent substrate (e.g., transparent substrate 410) in accordance with one or more embodiments of the present invention. In certain embodiments, second conductive pattern 430 may include a mesh formed by a second plurality of parallel conductive lines oriented in a first direction 520 and a second plurality of parallel conductive lines oriented in a second direction 525 that are disposed on a side of a transparent substrate (e.g., transparent substrate 410). One of ordinary skill in the art will recognize that the number of parallel conductive lines oriented in the first direction 520 and/or the number of parallel conductive lines oriented in the second direction 525 may vary based on an application or design. The second conductive pattern 430 may be substantially similar in size to the first conductive pattern 420. One of ordinary skill in the art will recognize that a size of the second conductive pattern 430 may vary based on an application or a design. In other embodiments, second conductive pattern 430 may include any other shape or pattern formed by one or more conductive lines or features (not independently illustrated). One of ordinary skill in the art will also recognize that second conductive pattern 430 is not limited to parallel conductive lines and could be any one or more of a predetermined orientation of line segments, a random orientation of line segments, curved line segments, conductive particles, polygons, or any other shape(s) or pattern(s) comprised of electrically conductive material (not independently illustrated) in accordance with one or more embodiments of the present invention.

In certain embodiments, the second plurality of parallel conductive lines oriented in the first direction 520 may be perpendicular (not shown) to the second plurality of parallel conductive lines oriented in the second direction 525, thereby forming a rectangle-type mesh. In other embodiments, the second plurality of parallel conductive lines oriented in the first direction 520 may be angled relative to the second plurality of parallel conductive lines oriented in the second direction 525, thereby forming a parallelogram-type mesh. One of ordinary skill in the art will recognize that the relative angle between the second plurality of parallel conductive lines oriented in the first direction 520 and the second plurality of parallel conductive lines oriented in the second direction 525 may vary based on an application or a design in accordance with one or more embodiments of the present invention.

In certain embodiments, a plurality of channel breaks 530 may partition second conductive pattern 430 into a plurality of row channels 320, each electrically isolated from the others (no electrical continuity). One of ordinary skill in the art will recognize that the number of channel breaks 530, the number of row channels 320, and/or the width of the row channels 320 may vary based on an application or design in accordance with one or more embodiments of the present invention. Each row channel 320 may route to a channel pad 540. Each channel pad 540 may route via one or more interconnect conductive lines 550 to an interface connector 560. Interface connectors 560 may provide a connection interface between a touch sensor (e.g., 130 of FIG. 2) and a controller (e.g., 210 of FIG. 2).

FIG. 5C shows a mesh area of a metal mesh touch sensor 130 in accordance with one or more embodiments of the present invention. In certain embodiments, a touch sensor 130 may be formed, for example, by disposing a first conductive pattern 420 on a top, or user-facing, side of a transparent substrate (e.g., transparent substrate 410) and disposing a second conductive pattern 430 on a bottom side of the transparent substrate (e.g., transparent substrate 410). In other embodiments, a touch sensor 130 may be formed, for example, by disposing a first conductive pattern 420 on a side of a first transparent substrate (e.g., transparent substrate 410), disposing a second conductive pattern 430 on a side of a second transparent substrate (e.g., transparent substrate 410), and bonding the first transparent substrate to the second transparent substrate. One of ordinary skill in the art will recognize that the disposition of the conductive pattern or patterns may vary based on the touch sensor 130 stack up in accordance with one or more embodiments of the present invention. In embodiments that use two conductive patterns, the first conductive pattern 420 and the second conductive pattern 430 may be offset vertically, horizontally, and/or angularly relative to one another. The offset between the first conductive pattern 420 and the second conductive pattern 430 may vary based on an application or a design. One of ordinary skill in the art will recognize that the first conductive pattern 420 and the second conductive pattern 430 may be disposed on substrate or substrates 410 using any process or processes suitable for disposing the conductive patterns on the substrate or substrates 410 in accordance with one or more embodiments of the present invention.

In certain embodiments, the first conductive pattern 420 may include a first plurality of parallel conductive lines oriented in a first direction (e.g., 505 of FIG. 5A) and a first plurality of parallel conductive lines oriented in a second direction (e.g., 510 of FIG. 5A) that form a mesh that is partitioned by a first plurality of channel breaks (e.g., 515 of FIG. 5A) into electrically partitioned column channels 310. In certain embodiments, the second conductive pattern 430 may include a second plurality of parallel conductive lines oriented in a first direction (e.g., 520 of FIG. 5B) and a second plurality of parallel conductive lines oriented in a second direction (e.g., 525 of FIG. 5B) that form a mesh that is partitioned by a second plurality of channel breaks (e.g., 530 of FIG. 5B) into electrically partitioned row channels 320. In operation, a controller (e.g., 210 of FIG. 2) may electrically drive one or more row channels 320 (or column channels 310) and touch sensor 130 senses touch on one or more column channels 310 (or row channels 320). In other embodiments, the disposition and/or the role of the first conductive pattern 420 and the second conductive pattern 430 may be reversed.

In certain embodiments, one or more of the plurality of parallel conductive lines oriented in the first direction (e.g., 505 of FIG. 5A, 520 of FIG. 5B) and one or more of the plurality of parallel conductive lines oriented in the second direction (e.g., 510 of FIG. 5A, 525 of FIG. 5A) may have a line width that varies based on an application or design, including, for example, micrometer-fine line widths. In addition, the number of parallel conductive lines oriented in the first direction (e.g., 505 of FIG. 5A, 520 of FIG. 5B), the number of parallel conductive lines oriented in the second direction (e.g., 510 of FIG. 5A, 525 of FIG. 5B), and the line-to-line spacing between them may vary based on an application or a design. One of ordinary skill in the art will recognize that the size, configuration, and design of each conductive pattern 420, 430 may vary based on an application or a design in accordance with one or more embodiments of the present invention. One of ordinary skill in the art will also recognize that touch sensor 130 depicted in FIG. 5C is illustrative but not limiting and that the size, shape, and design of the touch sensor 130 is such that there is substantial transmission of an image (not shown) of an underlying display device (e.g., 110 of FIG. 1) in actual use that is not shown in the drawing.

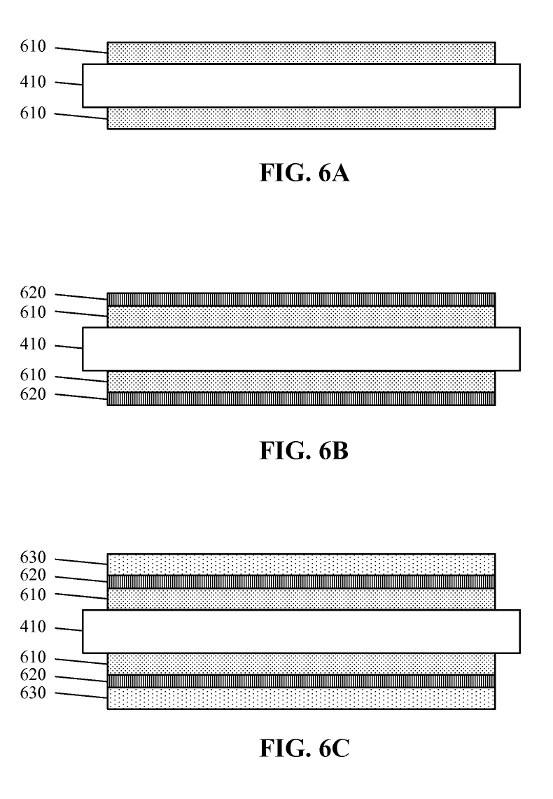

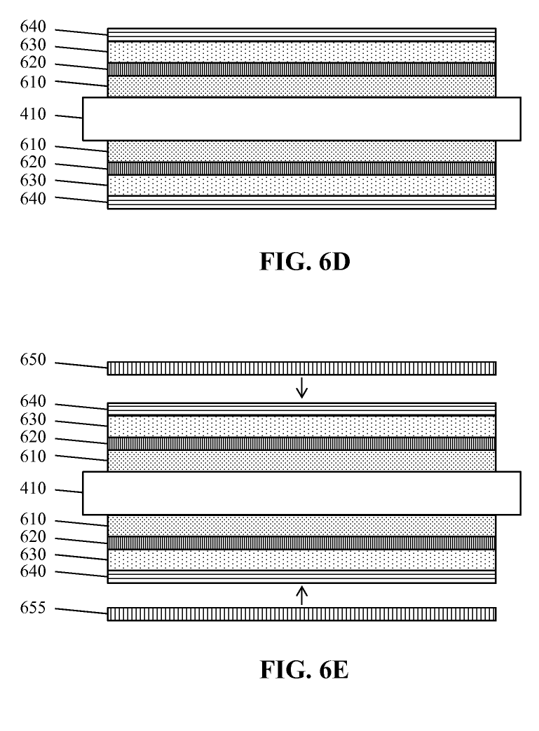

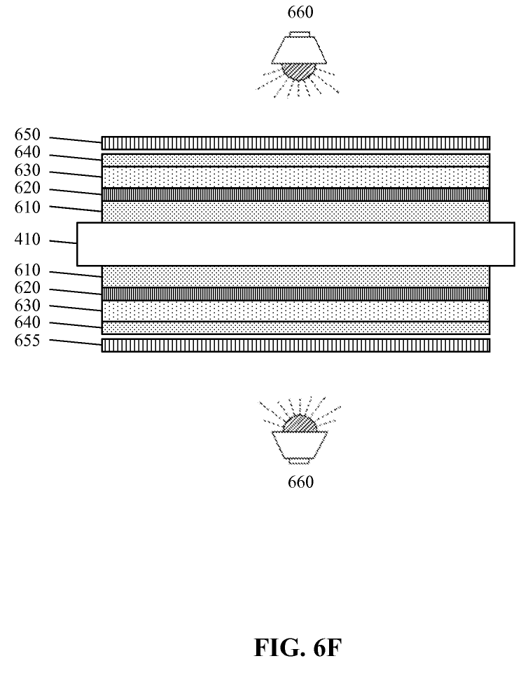

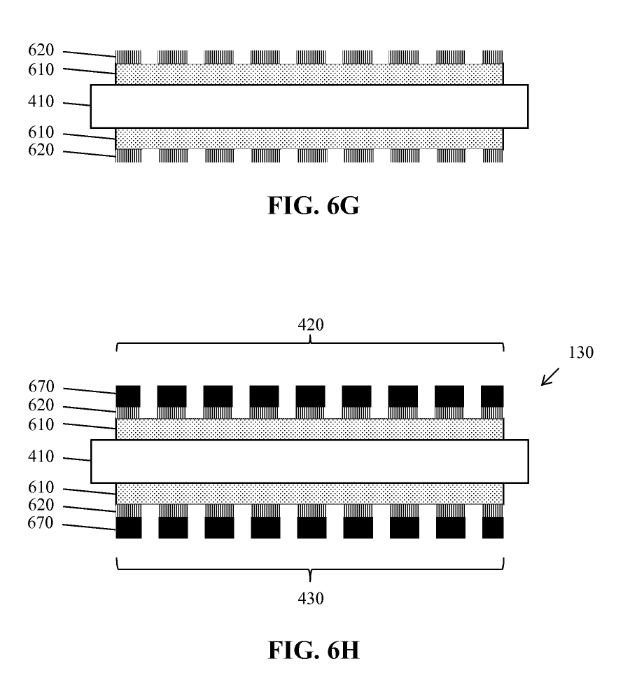

Conventional methods of fabricating a metal mesh touch sensor (e.g., 130 of FIG. 1) using photolithography are complex and expensive as explained with reference to FIGS. 6A through 6H.

FIG. 6A shows standoff layers 610 disposed on opposing sides of a transparent substrate 410. The transparent substrate 410 is typically composed of PET that is ultraviolet (“UV”) absorbent and has a thickness of approximately 50 micrometers. The standoff layers 610 raise the later formed metal layers (670 of FIG. 6H) off of the surface of the substrate 410 to reduce reflection. The standoff layers 610 are composed of acrylic and have a thickness in a range from approximately 1 nanometer to approximately 800 nanometers. The standoff layers 610 are in the liquid phase at the time of application and are applied to both sides of the transparent substrate 410 at the same time using one or more conventional application processes including dip coating, slot-die coating, spin coating, gravure printing, or reverse gravure printing.

Continuing in FIG. 6B, catalyst layers 620 are disposed on the opposing standoff layers 610. The catalyst layers 620 serve as a catalyst for processes that later dispose metal layers (670 of FIG. 6H) on the transparent substrate 410. The catalyst layers 620 are composed of a palladium-based catalytic material and have a thickness in a range between approximately 100 nanometers and approximately 200 nanometers. The catalyst layers 620 are in the liquid phase at the time of application and are applied to both sides of the transparent substrate 410 at the same time using one or more conventional application processes including dip coating, slot-die coating, spray coating, gravure printing, or reverse gravure printing.

Continuing in FIG. 6C, photoresist layers 630 are disposed on the opposing catalyst layers 620. The photoresist layers 630 are later patterned by UV radiation exposure, development, and stripping. The photoresist layers 630 are composed of negative photoresist material that, with respect to those portions of the negative photoresist that are exposed to UV radiation, remain on substrate 410 after development and stripping. The photoresist layers 630 are composed of an acrylic phenolic polymer and have a thickness in a range between approximately 200 nanometers and approximately 300 nanometers. The photoresist layers 630 are in the liquid phase at the time of application and are applied to both sides of the transparent substrate 410 at the same time using one or more conventional application processes including dip coating, slot-die coating, spray coating, gravure printing, or reverse gravure printing.

Continuing in FIG. 6D, oxygen protection layers 640 are disposed on the opposing photoresist layers 630. The oxygen protection layers 640 protect the photoresist layers 620 from undesirable polymerization by oxidation. The oxygen protection layers 640 are composed of polytetrafluoroethylene and have a thickness in a range between approximately 1 nanometer and approximately 500 nanometers. The oxygen protection layers 640 are in the liquid phase at the time of application and are applied to both sides of the transparent substrate 410 at the same time using one or more conventional application processes including dip coating, slot-die coating, spray coating, gravure printing, or reverse gravure printing.

Continuing in FIG. 6E, photomasks 650 and 655 are disposed on, or placed very near, the opposing oxygen protection layers 640. Photomasks 650 and 655 are composed of silica covered with material forming negative images of conductive patterns that are to be transferred to the photoresist layers 630 (e.g., negative photoresist application). Photomask 650 includes a negative image of a first conductive pattern (e.g., 420 of FIG. 4) and photomask 655 includes a negative image of a second conductive pattern (e.g., 430 of FIG. 4).

Continuing in FIG. 6F, portions of the photoresist layers 630 are exposed to UV radiation 660 through the photomasks 650 and 655. UV radiation 660 is typically UV-A, UV-B, or UV-C type radiation that is applied for an amount of time suitable to expose a given thickness of photoresist 630. The UV radiation 660 is applied to both sides of transparent substrate 410 at the same time. The UV radiation 660 incident on photomask 650 passes through a negative image of the first conductive pattern (e.g., 420 of FIG. 4) onto the photoresist layer 630 disposed on the first side of the transparent substrate 410. The UV radiation 660 incident on photomask 655 passes through a negative image of the second conductive pattern (e.g., 430 of FIG. 4) onto the photoresist layer 630 disposed on the second side of the transparent substrate 410. The UV exposed portions of the photoresist layers 630 are polymerized by the UV radiation 660.

Continuing in FIG. 6G, a developer (not independently shown) is applied to the opposing photoresist layers 630. The developer removes the unexposed portions of the photoresist layers 630, leaving a multi-layered image of the first conductive pattern (e.g., 420 of FIG. 4) on the first side of the transparent substrate 410 and a multi-layered image of the second conductive pattern (e.g., 430 of FIG. 4) on the second side of the transparent substrate 410. After development, the images remaining on substrate 410 include the stack up of standoff 610, catalyst 620, and photoresist 630. The remaining photoresist 630 is stripped leaving standoff 610 and catalyst 620 in the image of the first conductive pattern on the first side of the transparent substrate 410 and standoff 610 and catalyst 620 in the image of the second conductive pattern on the second side of the transparent substrate 410. Continuing in FIG. 6H, metal 670 is plated on the remaining catalyst 620, thereby forming the conductive patterns on opposing sides of the transparent substrate 410.

As described above, conventional methods of fabricating a metal mesh touch sensor using photolithography are complicated, time consuming, and expensive. As such, it is difficult to fabricate metal mesh touch sensors using photolithography at production volumes in an economically feasible manner. In addition, the large number of process steps required to fabricate the touch sensor increase the number of potential failure modes and reduces yield.

Accordingly, in one or more embodiments of the present invention, a catalytic photoresist and method of fabricating a metal mesh touch senor with catalytic photoresist simplifies the fabrication process, reduces the overall processing time, and reduces the cost of fabrication in a manner that allows for the high volume production of metal mesh touch sensors in an economically feasible manner. In addition, the simplicity of the method reduces failure modes and increases yield.

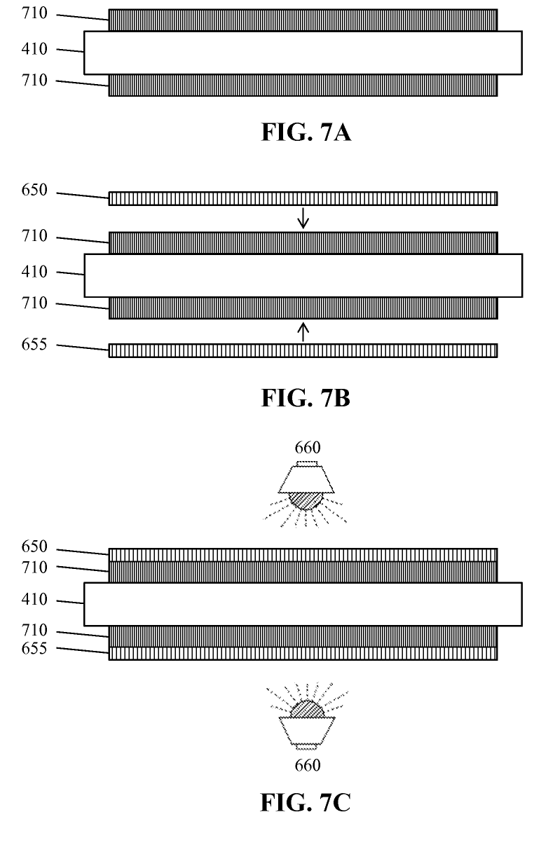

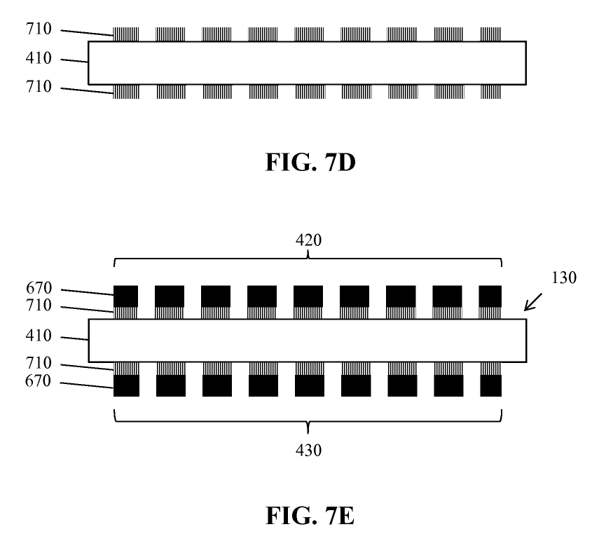

FIG. 7A shows catalytic photoresist 710 disposed on opposing sides of a transparent substrate 410 in accordance with one or more embodiments of the present invention. Catalytic photoresist 710 may be disposed on at least a portion of a first side of transparent substrate 410. Catalytic photoresist 710 may be disposed on at least a portion of a second side of transparent substrate 410. The catalytic photoresist 710 may be in the liquid phase at the time of application and may be applied to both sides of the transparent substrate 410 at the same time using one or more conventional application processes including dip coating, slot-die coating, spray coating, gravure printing, or reverse gravure printing. In certain embodiments, the catalytic photoresist 710 may have a thickness in a range between approximately 150 nanometers and approximately 700 nanometers. In other embodiments, the catalytic photoresist 710 may have a thickness in a range between approximately 200 nanometers and approximately 300 nanometers. One of ordinary skill in the art will recognize that the thickness of the catalytic photoresist 710 may vary in accordance with one or more embodiments of the present invention.

The catalytic photoresist 710 composition may include a negative photoresist component (not independently shown) and a catalyst component (not independently shown) that may include catalytic nanoparticles (not independently shown). In certain embodiments, the negative photoresist may be acrylic phenolic polymer. In other embodiments, the negative photoresist may be acrylic, epoxy, urethane, or combinations of one or more of the aforementioned chemistries. One of ordinary skill in the art will recognize that the negative photoresist composition may vary in accordance with one or more embodiments of the present invention. In certain embodiments, the catalytic nanoparticles may be silver nanoparticles. In other embodiments, the catalytic nanoparticles may be copper oxide nanoparticles. In still other embodiments, the catalytic nanoparticles may be palladium, platinum, gold, or organic metallic moieties of the aforementioned metals. One of ordinary skill in the art will recognize that the type of catalytic nanoparticles may vary based on an application or design in accordance with one or more embodiments of the present invention. In certain embodiments, the catalytic photoresist 710 composition may include negative photoresist component content in a range between approximately 30 percent and approximately 95 percent by weight and catalyst component content in a range between approximately 5 percent and approximately 70 percent by weight. In other embodiments, the catalytic photoresist 710 composition may include negative photoresist component content in a range between approximately 50 percent and approximately 70 percent by weight and catalyst component content in a range between approximately 30 percent and approximately 50 percent by weight.

Continuing in FIG. 7B, photomasks 650 and 655 are disposed on, or placed very near, the opposing catalytic photoresists 710. In certain embodiments, photomasks 650 and 655 may be composed of silica covered with material forming negative images of conductive patterns that are to be transferred to the catalytic photoresists 710 (e.g., negative photoresist application). One of ordinary skill in the art will recognize that the composition of photomasks 650 and 655 may vary in accordance with one or more embodiments of the present invention. Photomask 650 may include a negative image of a first conductive pattern (e.g., 420 of FIG. 4) and photomask 655 may include a negative image of a second conductive pattern (e.g., 430 of FIG. 4). In certain embodiments, an optional soft-bake (not shown) may be performed on the transparent substrate 410 prior to UV exposure. Soft-bake typically includes heating the transparent substrate 410 to a sufficient temperature for a sufficient amount of time to semi-harden the deposited catalytic photoresist 710 prior to UV-exposure. One of ordinary skill in the art will recognize that the temperature and the amount of time required to soft-bake may vary based on the composition and the applied thickness of the catalytic photoresist 710 in accordance with one or more embodiments of the present invention.

Continuing in FIG. 7C, portions of the catalytic photoresists 710 are exposed to UV radiation 660 through the photomasks 650 and 655. In certain embodiments, the UV radiation 660 may be UV-A radiation. In other embodiments, the UV radiation 660 may be UV-B radiation. In still other embodiments, the UV radiation 660 may be UV-C radiation. One of ordinary skill in the art will recognize that other UV radiation sources may be used in accordance with one or more embodiments of the present invention. The UV radiation 660 may be applied to both sides of transparent substrate 410 at the same time. The UV radiation 660 incident on photomask 650 passes through a negative image of the first conductive pattern (e.g., 420 of FIG. 4) onto catalytic photoresist 710 disposed on the first side of the transparent substrate 410. The UV radiation 660 incident on photomask 655 passes through a negative image of the second conductive pattern (e.g., 430 of FIG. 4) onto catalytic photoresist 710 disposed on the second side of the transparent substrate 410. The UV exposed portions of the catalytic photoresists 710 are polymerized by the UV radiation 660.

Continuing in FIG. 7D, a developer (not independently shown) is applied to the opposing catalytic photoresists 710. In certain embodiments, the developer may be composed of a water-based alkaline solution. In other embodiments, the developer may be composed of an organic solvent such as, for example, Carbitol™, or Dowanol™. One of ordinary skill in the art will recognize that the composition of the developer may vary with the composition of the catalytic photoresist in accordance with one or more embodiments of the present invention. The developer loosens or removes the unexposed portions of the catalytic photoresists 710, leaving a catalytic photoresist 710 image of the first conductive pattern (e.g., 420 of FIG. 4) on the first side of the transparent substrate 410 and a catalytic photoresist 710 image of the second conductive pattern (e.g., 430 of FIG. 4) on the second side of the transparent substrate 410. In certain embodiments, an optional hard-bake (not shown) may be performed on the transparent substrate 410 after development. Hard-bake typically includes heating the transparent substrate 410 to a sufficient temperature for a sufficient amount of time to stabilize and harden the developed catalytic photoresist 710 prior to stripping. One of ordinary skill in the art will recognize that the temperature and the amount of time required to hard-bake may vary based on the composition and the applied thickness of the catalytic photoresist 710 in accordance with one or more embodiments of the present invention. After development, any remaining catalytic photoresist 710 not exposed to UV radiation is stripped leaving catalytic photoresist 710 in the image of the first conductive pattern on the first side of the transparent substrate 410 and catalytic photoresist 710 the image of the second conductive pattern on the second side of the transparent substrate 410.

Continuing in FIG. 7E, metal 670 may be plated on remaining catalytic photoresist 710, thereby forming the conductive patterns (e.g., 420 and 430 of FIG. 4) on opposing sides of the transparent substrate 410. In certain embodiments, an electroless plating process may be used to electrolessly plate a first metal on the catalytic photoresist 710 images of the conductive patterns disposed on the substrate 410. In other embodiments, an immersion bath process may be used to immersion plate a first metal on the catalytic photoresist 710 images of the conductive patterns disposed on the substrate 410. One of ordinary skill in the art will recognize that other methods of disposing metal on the images of the catalytic photoresist 710 may be used in accordance with one or more embodiments of the present invention. In certain embodiments, the first metal may be copper. In other embodiments, the first metal may be copper alloy. One of ordinary skill in the art will recognize that other metals or metal alloys may be used in accordance with one or more embodiments of the present invention. In certain embodiments, more than one metal layer may be disposed on the remaining catalytic photoresist 710 in accordance with one or more embodiments of the present invention. In certain embodiments, a metal passivation layer, such as, for example, palladium, or a protective coating, may be applied over the metal 670 to protect the metal 670 from corrosion and other environmental failure modes.

Advantages of one or more embodiments of the present invention may include one or more of the following:

In one or more embodiments of the present invention, a catalytic photoresist may serve the purpose of both a catalyst and photoresist in a single layer that may be disposed on a transparent substrate with a single application process.

In one or more embodiments of the present invention, a catalytic photoresist may serve as a photoresist for the purpose of patterning the disposed catalytic photoresist on substrate and may serve as a catalyst for plating the patterned catalytic photoresist after exposure, development, and stripping.

In one or more embodiments of the present invention, a catalytic photoresist may be compatible with conventional processes for disposing photoresist on a transparent substrate.

In one or more embodiments of the present invention, a catalytic photoresist may be compatible with conventional processes for exposing photoresist disposed on a transparent substrate.

In one or more embodiments of the present invention, a catalytic photoresist may be compatible with conventional processes for applying a developer to photoresist disposed on a transparent substrate.

In one or more embodiments of the present invention, a catalytic photoresist may be compatible with conventional processes for stripping undesired photoresist from a transparent substrate.

In one or more embodiments of the present invention, a catalytic photoresist may be compatible with conventional electroless plating processes for disposing metal on a catalytic layer.

In one or more embodiments of the present invention, a catalytic photoresist may be compatible with conventional immersion bathing processes for disposing metal on a catalytic layer.

In one or more embodiments of the present invention, a method of fabricating a metal mesh touch sensor with catalytic photoresist may use conventional software applications used to design one or more conductive patterns in a software application.

In one or more embodiments of the present invention, a method of fabricating a metal mesh touch sensor with catalytic photoresist reduces the number of layers required to fabricate a touch sensor over that of a conventional metal mesh touch sensor.

In one or more embodiments of the present invention, a method of fabricating a metal mesh touch sensor with catalytic photoresist reduces the material cost required to fabricate a touch sensor of fabrication over that of a conventional metal mesh touch sensor.

In one or more embodiments of the present invention, a method of fabricating a metal mesh touch sensor with catalytic photoresist reduces the number of process steps required to fabricate the touch sensor over that of a conventional metal mesh touch sensor.

In one or more embodiments of the present invention, a method of fabricating a metal mesh touch sensor with catalytic photoresist reduces fabrication time over that of a conventional metal mesh touch sensor.

In one or more embodiments of the present invention, a method of fabricating a metal mesh touch sensor with catalytic photoresist reduces fabrication complexity over that of a conventional metal mesh touch sensor.

While the present invention has been described with respect to the above-noted embodiments, those skilled in the art, having the benefit of this disclosure, will recognize that other embodiments may be devised that are within the scope of the invention as disclosed herein. Accordingly, the scope of the invention should be limited only by the appended claims.

What is claimed is:

1. A catalytic photoresist composition comprising:
a negative photoresist component; and
a catalyst component comprising catalytic nanoparticles,
wherein the negative photoresist component content is in a range between 30 percent and 95 percent of the composition by weight, and
wherein the catalyst component content is in a range between 5 percent and 70 percent of the composition by weight.

2. The composition of claim 1, wherein the negative photoresist comprises an acrylic phenolic polymer.

3. The composition of claim 1, wherein the catalytic nanoparticles comprise silver nanoparticles.

4. The composition of claim 1, wherein the catalytic nanoparticles comprise copper oxide nanoparticles.

5. The composition of claim 1, wherein the negative photoresist component content is in a range between 50 percent and 70 percent of the composition by weight, and wherein the catalyst component content is in a range between 30 percent and 50 percent of the composition by weight.

6. A method of fabricating a metal mesh touch sensor comprising:
disposing catalytic photoresist on at least a portion of a first side of a transparent substrate;
disposing catalytic photoresist on at least a portion of a second side of the substrate;
exposing at least a portion of the catalytic photoresist disposed on the first side of the substrate to ultraviolet radiation through a first photomask wherein the first photomask comprises a negative image of a first conductive pattern;
exposing at least a portion of the catalytic photoresist disposed on the second side of the substrate to ultraviolet radiation through a second photomask wherein the second photomask comprises a negative image of a second conductive pattern;
applying a developer to the catalytic photoresist disposed on the substrate;
stripping catalytic photoresist not exposed to ultraviolet radiation; and
plating the at least portions of the catalytic photoresist exposed to ultraviolet radiation.

7. The method of claim 6, wherein the catalytic photoresist comprises:
a negative photoresist component; and
a catalyst component comprising catalytic nanoparticles,
wherein the negative photoresist component content is in a range between 30 percent and 95 percent of the composition by weight, and
wherein the catalyst component content is in a range between 5 percent and 70 percent of the composition by weight.

8. The method of claim 7, wherein the negative photoresist comprises an acrylic phenolic polymer.

9. The method of claim 7, wherein the catalytic nanoparticles comprise silver nanoparticles.

10. The method of claim 7, wherein the catalytic nanoparticles comprise copper oxide nanoparticles.

11. The method of claim 7, wherein the negative photoresist component content is in a range between 50 percent and 70 percent of the composition by weight, and wherein the catalyst component content is in a range between 30 percent and 50 percent of the composition by weight.

12. The method of claim 6, wherein the plating comprises electroless plating the at least portions of the catalytic photoresist material with a first metal.

13. The method of claim 12, wherein the first metal comprises copper.

14. The method of claim 6, wherein the plating comprises immersion bath plating the at least portions of the catalytic photoresist material with a first metal.

15. The method of claim 14, wherein the first metal comprises copper.

16. The method of claim 6, wherein the catalytic photoresist is disposed on the substrate by slot die coating.

17. The method of claim 6, wherein the catalytic photoresist is disposed on the substrate by spray coating.

18. The method of claim 6, wherein the catalytic photoresist is disposed on the substrate by spin coating.

19. The method of claim 6, wherein the catalytic photoresist is disposed on the substrate by a gravure printing process.

20. The method of claim 6, wherein the catalytic photoresist material is on the substrate by a reverse gravure printing process.
